(19) United States
(12) Patent Application Publication
(10) Pub. No.: US 2009/0039732 A1
(43) Pub. Date: Feb. 12, 2009

(54) Surface acoustic wave device

(76) Inventors: Satoshi Orito, Yokohama (JP); Toru Takezaki, Yokohama (JP); Koichi Wada, Yokohama (JP)

Correspondence Address: ARENT FOX LLP, 1050 CONNECTICUT AVENUE, N.W., SUITE 400, WASHINGTON, DC, 20036, US

(21) Appl. No.: 11/987,269

(22) Filed: Nov. 28, 2007

(30) Foreign Application Priority Data
Nov. 28, 2006 (JP) 2006-320486

(51) Int. Cl. H01L 41/053

(52) U.S. Cl. 310/313 R

(57) ABSTRACT

A surface acoustic wave device includes a SAW device chip mounted on a substrate, and a lid provided so as to cover the SAW device. A maximum thickness of a ceiling portion of the lid that does not face the SAW device chip is greater than that of another ceiling portion of the lid that faces the SAW device chip.

### BACKGROUND OF THE INVENTION

1. Field of the Invention

The present invention generally relates to surface acoustic wave devices, and more particularly, to a surface acoustic wave device having a surface acoustic wave device chip covered by a lid.

2. Description of the Related Art

A surface acoustic wave device (SAW device) is capable of exciting an acoustic wave by applying power to comb electrodes of an interdigital transducer (IDT) formed on a piezoelectric substrate. The SAW device is widely used for various circuits that process radio signals in a frequency band of, for example, 45 MHz to 2 GHz. Examples of these circuits are bandpass filters for transmission, bandpass filters for reception, local oscillation filters, antenna duplexers, intermediate frequency filters, and FM modulators.

Recently, signal processing devices have been downsized and the SAW devices have been required to have reduced sizes. Particularly, filters used for television tuners are designed to have a reduced size, especially, a reduced height, and surface-mountable SAW filters applied thereto are demanded to have a reduced size, especially, a reduced height. The SAW device needs a space above the comb electrodes of the IDT that is a key part involved in performance.

### SUMMARY OF THE INVENTION

According to an aspect of the present invention, there is provided a less-expensive SAW device having a reduced size including a reduced height.

According to another aspect of the present invention, there is provided a surface acoustic wave device including: a SAW device chip mounted on a substrate; and a lid provided so as to cover the SAW device, wherein a maximum thickness of a ceiling portion of the lid that does not face the SAW device chip is greater than that of another ceiling portion of the lid that faces the SAW device chip.

### BRIEF DESCRIPTION OF THE DRAWINGS

FIG. 1 is a cross-sectional view of a SAW device of a first related art;

FIG. 2 is a cross-sectional view of a SAW device of a second related art;

FIG. 3A is a plan view of a SAW device in accordance with a first embodiment, FIG. 3B is a plan view of the SAW device seen through a lid, and FIG. 3C is a cross-sectional view taken along a line A-A shown in FIG. 3A;

FIGS. 4A through 4E are cross-sectional views showing a method for manufacturing the SAW device in accordance with the first embodiment;

FIG. 5 is a cross-sectional view of a SAW device in accordance with a second embodiment;

FIG. 6 is a cross-sectional view of a SAW device in accordance with a third embodiment;

FIG. 7 is a cross-sectional view of a SAW device in accordance with a fourth embodiment;

FIGS. 8A and 8B respectively show stress distributions of a comparative example and the fourth embodiment because of change in inner pressure computed by the finite element method, and FIGS. 8C and 8D are respectively cross-sectional views of the comparative example and the fourth embodiment used in the computation.

FIG. 9A is a plan view of a SAW device having a region in which the ceiling portion of the lid is comparatively thick, and FIG. 9B is a plan view of the SAW device seen through the lid;

FIG. 10A is a plan view of a SAW device having another region in which the ceiling portion of the lid is comparatively thick, and FIG. 10B is a plan view of the SAW device seen through the lid;

FIG. 11A is a plan view of a SAW device having an arrangement of multiple regions in which the ceiling portion of the lid is comparatively thick, and FIG. 11B is a plan view of the SAW device seen through the lid;

FIG. 12A is a plan view of a SAW device having another arrangement of multiple regions in which the ceiling portion of the lid is comparatively thick, and FIG. 12B is a plan view of the SAW device seen through the lid;

FIG. 13A is a plan view of a SAW device having yet another arrangement of multiple regions in which the ceiling portion of the lid is comparatively thick, and FIG. 13B is a plan view of the SAW device seen through the lid;

FIG. 14A is a plan view of a SAW device having a further arrangement of multiple regions in which the ceiling portion of the lid is comparatively thick, and FIG. 14B is a plan view of the SAW device seen through the lid; and

FIG. 15A is a plan view of a SAW device having a further arrangement of multiple regions in which the ceiling portion of the lid is comparatively thick, and FIG. 15B is a plan view of the SAW device seen through the lid.

### DESCRIPTION OF THE PREFERRED EMBODIMENTS

In order to facilitate better understanding of the present invention, a description will now be given of related art.

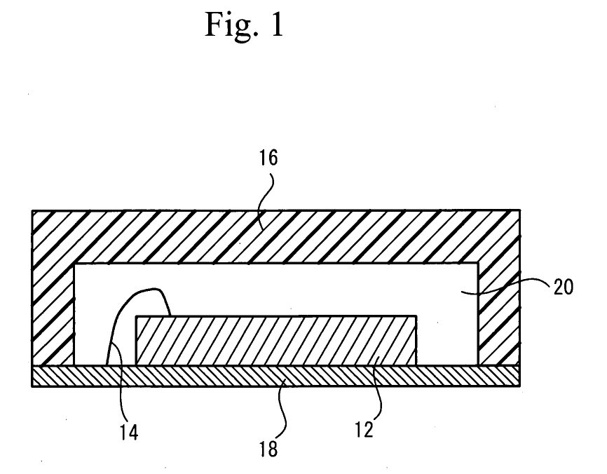

FIG. 1 is a cross-sectional view of a SAW device in accordance with a first related art: A SAW device chip 12 is mounted on a substrate 18. The SAW device chip 12 is electrically connected to an external circuit via metal lines (not shown for the sake of simplicity) formed on the substrate 18 by wires 14. A lid 16 made of resin is provided on the substrate 18 so as to cover the SAW device chip 12 and define a space or cavity 20 above the SAW device chip 12. In this manner, the SAW device chip 12 is sealed with the lid 16.

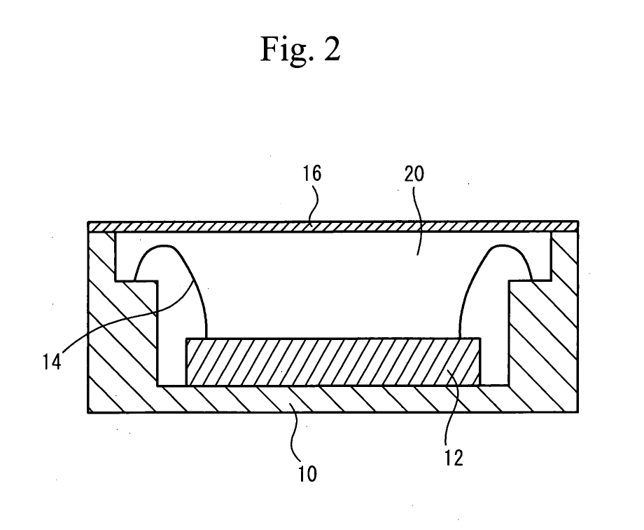

FIG. 2 is a cross-sectional view of a SAW device in accordance with a second related art. The SAW device chip 12 is housed in a ceramic package 10. The SAW device chip 12 is electrically connected to an external circuit via metal lines formed on the ceramic package 10 and connected to the SAW device chip 12 by wires 14. The lid 16, which is a metal lid, is welded to the top of the ceramic package 10 so as to define a cavity above the SAW device chip 12. In this manner, the SAW device chip 12 is sealed with the lid 16.

Japanese Patent Application Publication No. 2006-67530 discloses a dent formed in the lid 16 made of resin in order to prevent the loop-shaped wires 14 from contacting the lid 16.

The SAW device chip 12 of the first related art is sealed with the resin lid 16. In order to reduce the height of the SAW device, the lid 16 is required to have a reduced thickness. However, the reduced thickness degrades the mechanical strength of the lid 16. In this regard, the lid 16 must have an appropriate thickness enough to ensure the mechanical strength. This prevents reduction in the height of the SAW device.

The ceramic package 10 and the metal lid 16 of the second related art have strong mechanical strength. Thus, the lid 16 may be reduced in thickness. The ceramic package 10 is expensive, and the SAW device of the second related art is thus expensive.

The proposal of the above-mentioned publication uses the dent formed in the lid 16. It is thus necessary to reduce the distance between the SAW device chip 12 and the lid 16. However, the dent portion of the lid 16 is mechanically weak and makes it difficult to reduce the height.

The present invention has been made in view of the above-mentioned circumstance and provides a less-expensive SAW device having a reduced size including a reduced height.

### FIRST EMBODIMENT

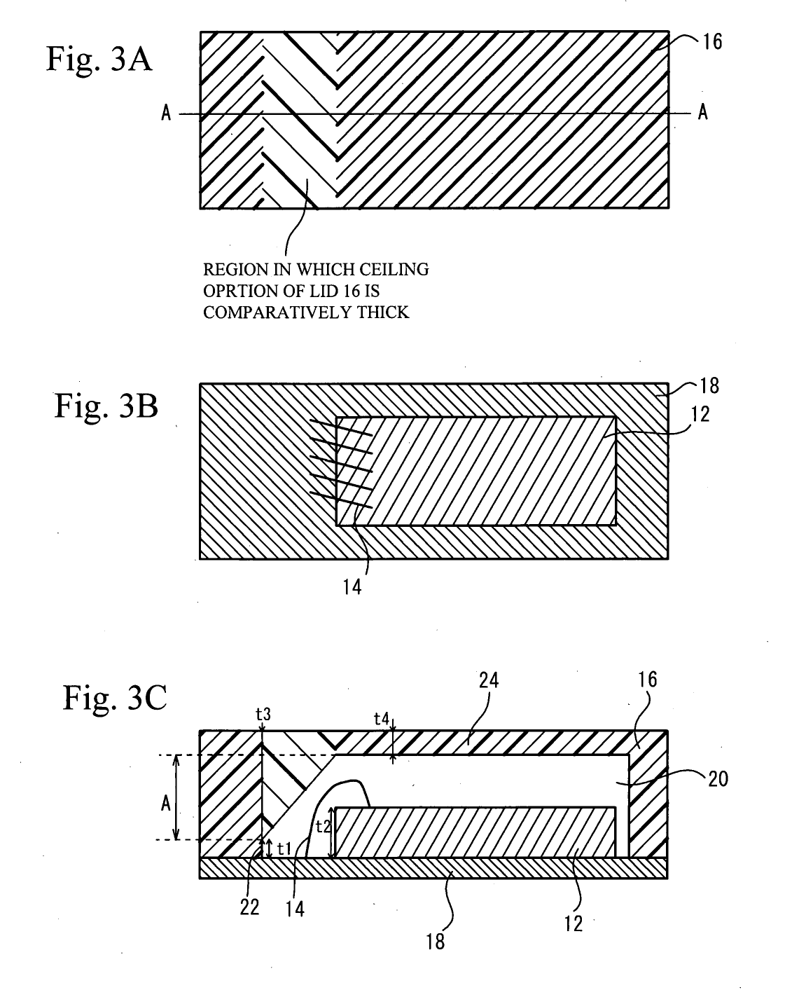

FIG. 3A is a plan view of a SAW device in accordance with a first embodiment, and FIG. 3B is a plan view of the SAW device in which the inside of the SAW device is seen through the lid 16. FIG. 3C is a cross-sectional view taken along a line A-A. Referring to FIG. 3C, the SAW device chip 12 is mounted on the glass-epoxy substrate 18. A cavity 20 is provided above the SAW device chip 12, and the lid 16 made of epoxy region is provided so as to cover the SAW device chip 12. In this manner, the SAW device chip 12 is sealed with the lid 16. An inner side surface 22 of the lid 16 is perpendicular to the substrate 18. The height t1 of the inner side surface 22 of the lid 16 is less than the height t2 of the SAW device chip 12. The inner side surface 22 of the lid 16 contacts the cavity 20 and connects to a ceiling portion 24 of the lid 16 having the maximum thickness. The SAW device chip 12 is electrically connected to an external circuit by metal interconnection lines of the substrate 18 to which wires 14 extending from the SAW device chip 12 are connected. The wires 14 may be made of gold. The maximum thickness t3 of the ceiling portion 24 of the lid that does not face the SAW device chip 12 in a region in which the wires 14 are provided is greater than the maximum thickness t4 of the ceiling portion 24 of the lid 16 that faces the SAW device chip 12. The thickness of the ceiling portion 24 of the lid that does not face the SAW device chip 12 in the region in which the wires 14 are provided increases towards the inner side surface 22 of the lid 16 at a constant rate of change. That is, the rate of change of the thickness of the ceiling portion 24 of the lid 16 is constant. The ceiling portion 24 of the lid 16 is defined as a portion above the cavity 20.

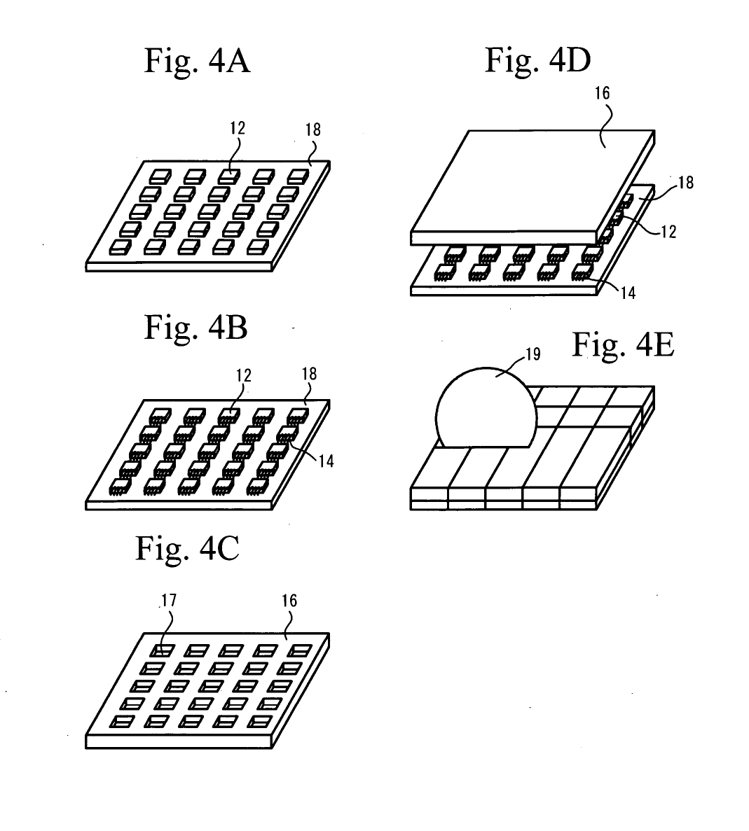

A description will now be given of a method for manufacturing the SAW device in accordance with the first embodiment with reference to FIGS. 4A through 4E. As shown in FIG. 4A, SAW device chips 12 are periodically mounted in rows and columns on the substrate 18 having metal interconnections lines. As shown in FIG. 4B, the SAW device chips 12 are electrically connected to the metal interconnection lines of the substrate 18 by the wires 14.

FIG. 4C shows the lid 16. The lid 16 has dents periodically arranged in rows and columns. The dents 17 are provided to cover the SAW device chips 12 when the lid 16 overlaps with the substrate 18. The dents 17 have a shape such that the portion of the lid that is located in the region for the wires 14 and does not face the SAW device chip 12 is comparatively thick.

As shown in FIG. 4D, the substrate and the lid 16 are overlapped with each other and are bonded by an adhesive agent. Then, the assembly is heated with pressure, so that the SAW device chips 12 can be hermetically sealed with the lid 16. Then, as shown in FIG. 4E, a dicing blade 19 is used to divide the assembly of the substrate 18 and the lid 16 into pieces each including one SAW device chip 12. In this manner, the SAW devices of the first embodiment are manufactured.

According to the first embodiment, the maximum thickness t3 of the ceiling portion 24 of the lid that does not face the SAW device chip 12 in the region in which the wires 14 are provided is greater than the maximum thickness t4 of the ceiling portion 24 of the lid 16 that faces the SAW device chip 12. Thus, stress applied to the ceiling portion 24 of the lid 16 can be distributed, and stress concentration on a part of the ceiling portion 24 can be avoided. Thus, the mechanical strength of the lid 16 can be enhanced. It is therefore possible to reduce the thickness t4 of the ceiling portion 24 of the lid that faces the SAW device chip 12 and to reduce the height of the SAW device.

According to the first embodiment, the inner side surface 22 of the lid 16 is perpendicular to the substrate 18. It is thus possible to form the lid 16 along the wires 14 and to avoid wasted space. Thus, the SAW device has a reduced size.

Further, according to the first embodiment, the height t1 of the inner side surface 22 of the lid 16 is less than the height t2 of the SAW device chip 12. It is thus possible to ensure an increased thickness of the ceiling portion 24 of the lid 16 that does not face the SAW device chip 12 in the region in which the wires 14 are provided, as compared to the case where the height t1 of the inner side surface 22 of the lid 16 is greater than the height t2 of the SAW device chip 12. It is therefore possible to increase the strength of the lid 16 and reduce the height of the SAW device.

Furthermore, according to the first embodiment, the thickness of the ceiling portion 24 of the lid that does not face the SAW device chip 12 in the region in which the wires 14 are provided increases towards the inner side surface 22 of the lid 16 at a constant rate of change. The shape of the lid 16 is simple, so that the SAW device can be manufactured easily.

The lid 16 may be made of not only resin but also another material. Preferably, epoxy resin or another less-expensive material is used for the lid 16 in order to provide the SAW devices inexpensively.

In the above description of the first embodiment, the height of the inner side surface 22 of the lid 16 is less than the height t2 of the SAW device chip 12. Alternatively, the height t1 of the inner side surface 22 of the lid 16 may be greater than the height t2 of the SAW device chip 12, when the maximum thickness t3 of the ceiling portion 24 of the lid 16 that does not face the SAW device chip 12 can be made greater than the maximum thickness t4 of the ceiling portion 24 of the lid that faces the SAW device chip 12. Even in the above alternative, the height of the SAW device can be reduced.

### SECOND EMBODIMENT

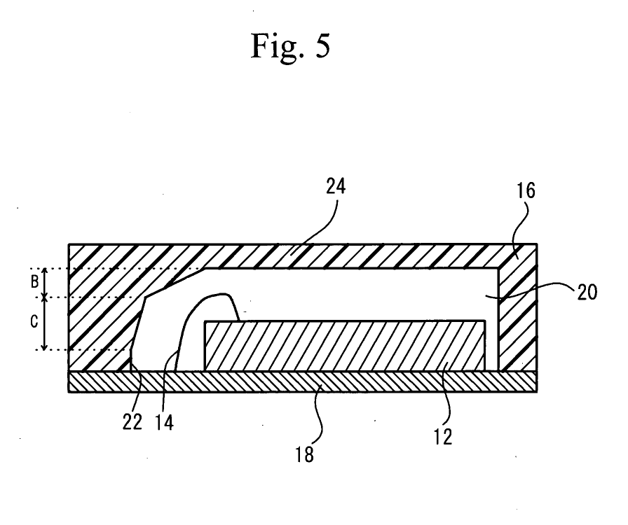

FIG. 5 is a cross-sectional view of a SAW device in accordance with a second embodiment. Referring to FIG. 5, the thickness of the ceiling portion 24 of the lid that does not face the SAW device chip 12 in the region in which the wires 14 are not provided increases towards the inner side surface 22 of the lid 16 at two different constant rates of change. The rate of change of the thickness of the ceiling portion 24 of the lid 16 in a section B differs from that in a section C. The other structures of the second embodiment are the same as those of the first embodiment shown in FIG. 3C.

According to the second embodiment, the thickness of the ceiling portion 24 of the lid that does not face the SAW device chip 12 in the region in which the wires 14 are not provided increases towards the inner side surface 22 of the lid 16 at two different constant rates of change. It is thus possible to more appropriately arrange the lid 16 along the wires 14 than the first embodiment. The maximum thickness of the ceiling portion 24 of the lid 16 that does not face the SAW device chip 12 in the region in which the wires 14 are provided can be increased, as compared with the first embodiment. Thus, the strength of the lid 16 can be enhanced. This means that the second embodiment can realize a further reduced height of the SAW device, as compared to the first embodiment.

The second embodiment is not limited to the above-mentioned arrangement in which the thickness of the ceiling portion 24 of the lid that does not face the SAW device chip 12 in the region in which the wires 14 are not provided increases towards the inner side surface 22 of the lid 16 at two different constant rates of change. The second embodiment includes another arrangement in which the thickness of the ceiling portion 24 of the lid that does not face the SAW device chip 12 in the region in which the wires 14 are not provided increases towards the inner side surface 22 of the lid 16 at three different constant rates of change or more.

### THIRD EMBODIMENT

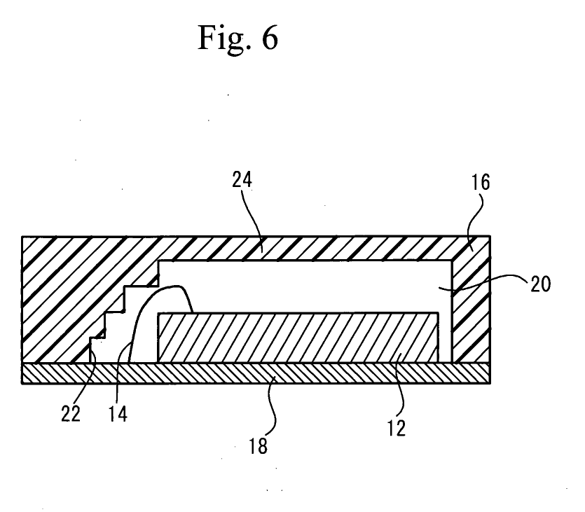

FIG. 6 is a cross-sectional view of a SAW device in accordance with a third embodiment. Referring to FIG. 6, the thickness of the ceiling portion 24 of the lid 16 that does not face the SAW device chip 12 in the region in which the wires 14 are provided increases stepwise towards the inner side surface 22 of the lid 16. The other structures of the third embodiment are the same as those of the first embodiment shown in FIG. 3C.

### FOURTH EMBODIMENT

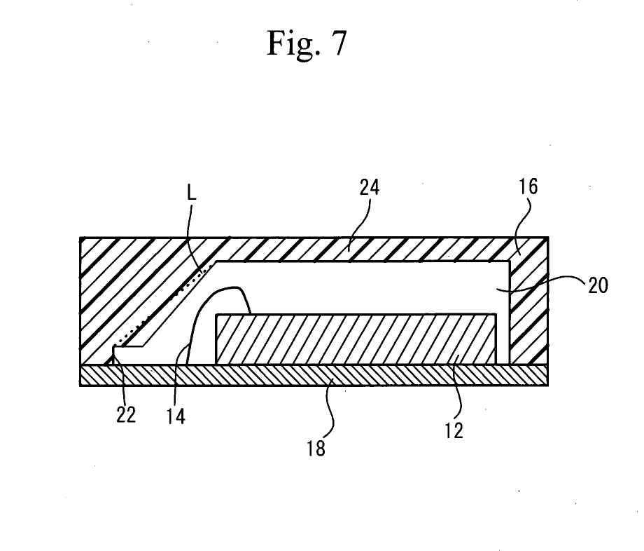

FIG. 7 is a cross-sectional view of a SAW device in accordance with a fourth embodiment. Referring to FIG. 7, the thickness of a part of the ceiling portion 24 of the lid that does not face the SAW device chip 12 in the region in which the wires 14 are provided is greater than the thickness that increases towards the inner side surface 22 at a constant rate of change. In other words, the thickness of a part of the ceiling portion 24 of the lid 16 that does not face the SAW device chip 12 in the region in which the wires 14 are provided protrudes from a broken line L downwards. The other structures of the fourth embodiment are the same as those of the first embodiment shown in FIG. 3C.

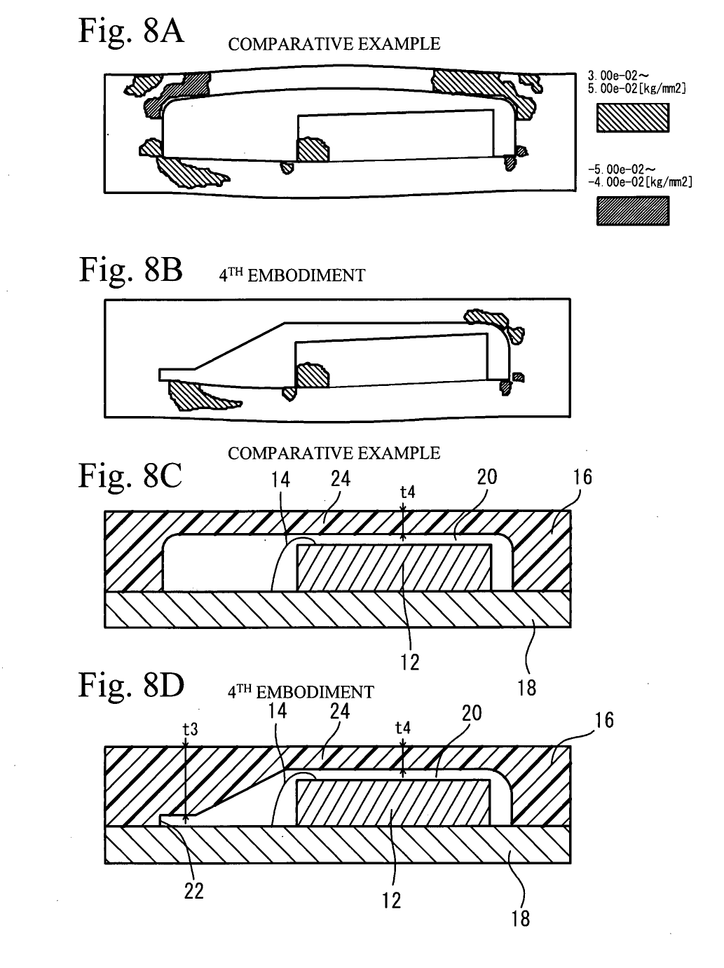

FIGS. 8A and 8B respectively show stress distributions of a comparative example and the fourth embodiment because of change in inner pressure computed by the finite element method. FIGS. 8C and 8D are respectively cross-sectional views of the comparative example and the fourth embodiment used in the computation. Each of the comparative example and the fourth embodiment has an outer shape in which each device is 1.0 mm high and 4.3 mm wide and the substrate 18 is 0.2 mm thick. The maximum thickness t4 of the ceiling portion 24 of the lid of the SAW device of the comparative example is 0.2 mm. The maximum thickness t4 of the ceiling portion 24 of the lid 16 that faces the SAW device chip 12 of the SAW device of the fourth embodiment is 0.2 mm, and the maximum thickness t3 of the ceiling portion 24 that does not face the SAW device chip 12 is 0.7 mm.

Referring to FIGS. 8A and 8B, there are illustrated two stress distributions observed when the inner pressure of the SAW devices is changed to 1.7 times the atmospheric pressure. A first distribution has stress applied to the SAW device in the range of 3.0×10⁻² kg/mm² to 5.0×10⁻² kg/mm². A second distribution has stress applied to the SAW device in the range of −4.0×10⁻² kg/mm² to −5.0×10⁻² kg/mm². The ceiling portion 24 of the lid 16 of the comparative example has a large stress distribution. In contrast, the ceiling portion 24 of the lid 16 of the fourth embodiment has a small stress distribution. Further, the fourth embodiment has less deformation than the comparative example.

According to the fourth embodiment, the thickness of a part of the ceiling portion 24 of the lid 16 that does not face the SAW device chip 12 in the region in which the wires 14 are provided is greater than the thickness that increases towards the inner side surface of the lid 16 at a constant rate of change. Thus, the lid 16 of the fourth embodiment has greater strength than that of the first embodiment, so that the height of the fourth embodiment can be further reduced.

The second and third embodiments may be varied like the fourth embodiment. That is, in the second and third embodiments, the thickness of a part of the ceiling portion 24 of the lid 16 that does not face the SAW device chip 12 in the region in which the wires 14 are provided is made greater than the thickness that increases towards the inner side surface of the lid 16 at a constant rate of change. This facilitates further reduction in the height of the SAW device.

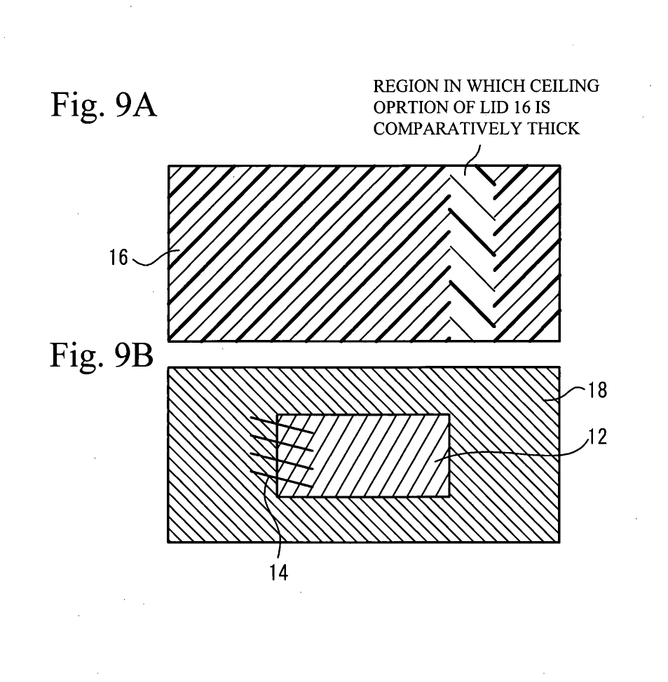

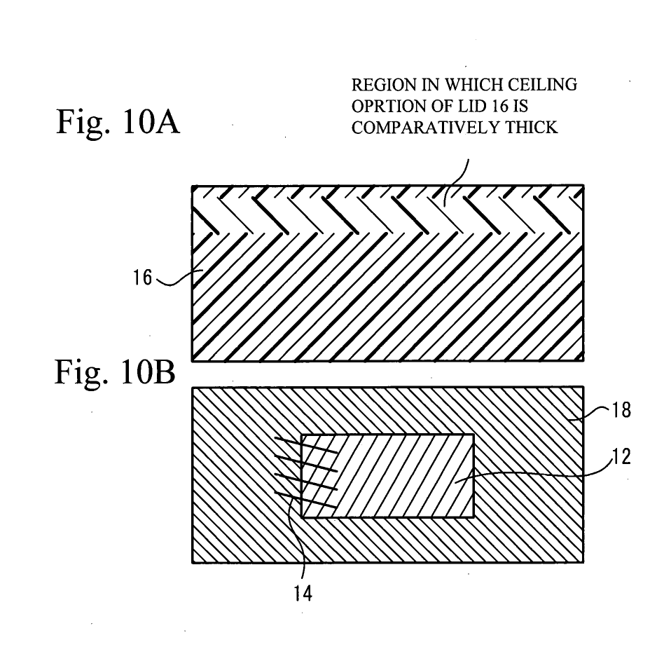

The above description of the first through fourth embodiments shows exemplary arrangements in which the maximum thickness of the ceiling portion 24 of the lid that does not face the SAW device chip 12 in the region in which the wires 14 are provided is greater than the maximum thickness of the ceiling portion 24 of the lid 16 that does not face the SAW device chip 12. The first through fourth embodiments are not limited to the above arrangement but may have another arrangement as shown in FIG. 9 in which the maximum thickness of the ceiling portion 24 of the lid 16 is available in another region opposite to the region in which the wires 14 are provided across the SAW device chip 12. Further, as shown in FIGS. 10A and 10B, the maximum thickness of the ceiling portion 24 of the lid 16 may be available in a region located in a direction perpendicular to the region in which the wires 14 are provided.

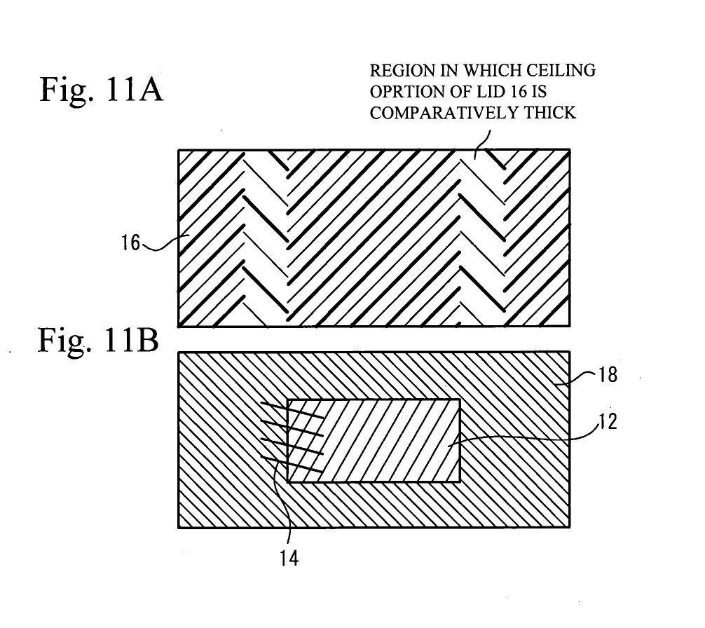

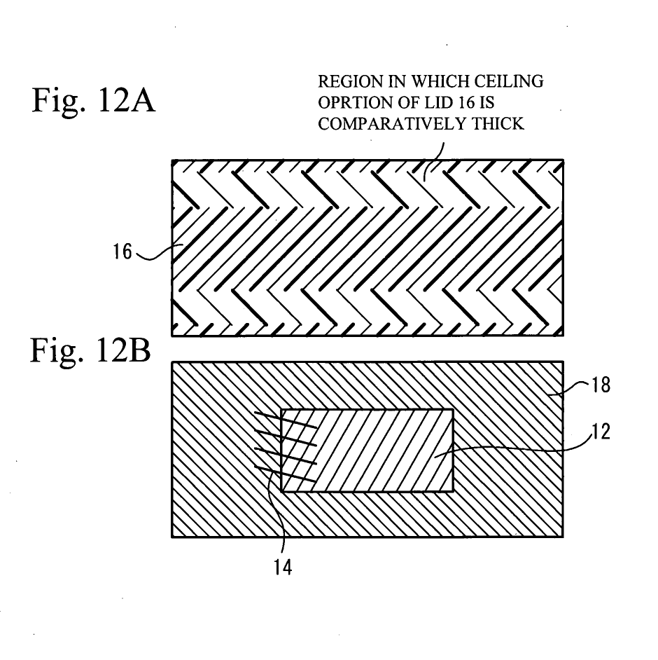

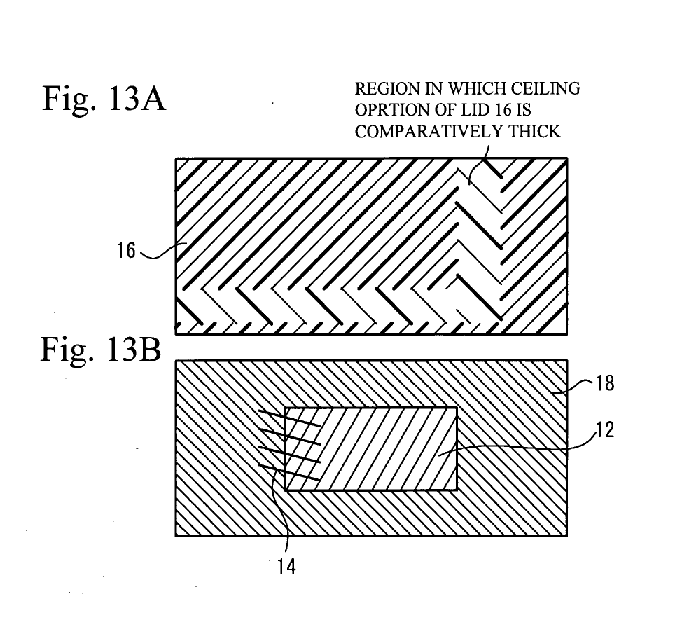

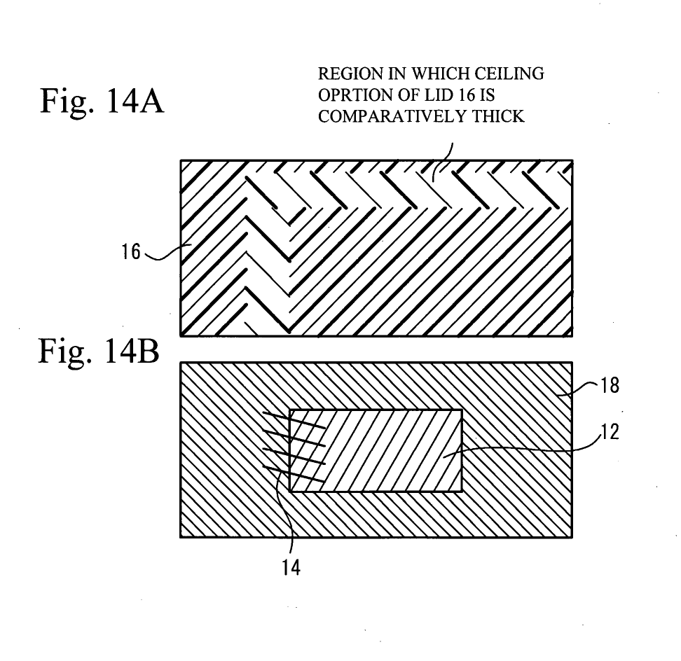

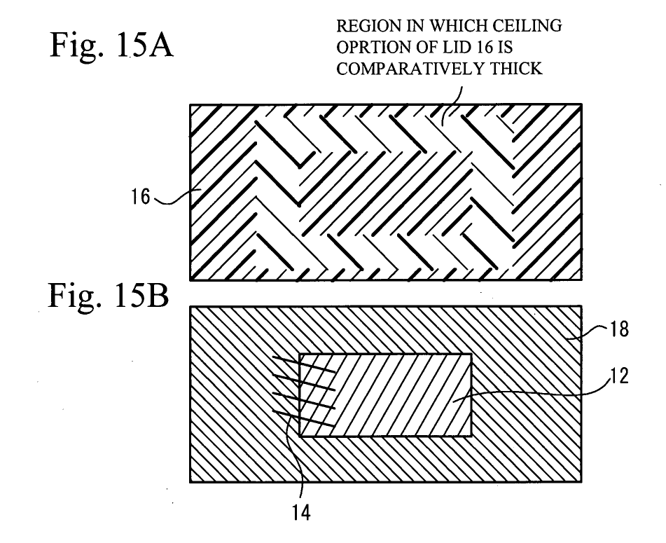

As shown in FIGS. 11A and 11B, the maximum thickness of the ceiling portion 24 of the lid 16 may be available in the first region in which the wires 14 are provided and a second region opposite to the first region across the SAW device chip 12. As shown in FIGS. 12A and 12B, the maximum thickness of the ceiling portion 24 of the lid 16 may be available in a first region located in a direction perpendicular to the region in which the wires 14 are provided, and a second region opposite to the first region across the SAW device chip 12. As shown in FIGS. 13A and 13B, the maximum thickness of the ceiling portion 24 of the lid 16 may be available in a first region opposite to the region in which the wires 14 are provided across the SAW device chip 12 and a second region that is perpendicular to the first region and form an L-shaped region together with the first region. As shown in FIGS. 14A and 14B, the maximum thickness of the ceiling portion 24 of the lid 16 may be available in a first region in which the wires 14 are provided and a second region that is perpendicular to the first region and forms an L-shaped region together with the first region. Further, as shown in FIGS. 15A and 15B, the maximum thickness of the ceiling portion 24 of the lid 16 may be available in a region provided so as to surround the SAW device chip 12. The maximum thickness of the ceiling portion 24 of the lid 16 that does not face the SAW device chip 12 is required to be greater than the maximum thickness of the ceiling portion 24 of the lid 16 that faces the SAW device chip 12. In order to efficiently utilize the wasted space for providing the wires, the ceiling portion 24 of the lid 16 is preferably made in the region in which the wires 14 are provided and the ceiling portion 24 does not face the SAW device chip 12.

The first through fourth embodiments may be applied to the arrangements shown in FIGS. 11A through 15B in which the maximum thickness of the ceiling portion 24 of the lid 16 is available in two regions or more further out than the SAW device chip 12.

The present invention is not limited to the specifically disclosed embodiments, but variations and modifications may be made without departing from the scope of the present invention.

The present application is based on Japanese Patent Application No. 2006-320486, the entire disclosure of which is hereby incorporated by reference.

What is claimed is:

1. A surface acoustic wave device comprising:
a SAW device chip mounted on a substrate; and
a lid provided so as to cover the SAW device,
wherein a maximum thickness of a ceiling portion of the lid that does not face the SAW device chip is greater than that of another ceiling portion of the lid that faces the SAW device chip.

2. The surface acoustic wave device as claimed in claim 1, further comprising wires for electrically connecting the SAW device chip to an external circuit.

3. The surface acoustic wave device as claimed in claim 1, wherein the maximum thickness of the ceiling portion of the lid that does not face the SAW device chip in a region in which the wires are provided is greater than the maximum thickness of the another ceiling portion of the lid that faces the SAW device chip.

4. The surface acoustic wave device as claimed in claim 1, wherein the lid has an inner side surface perpendicular to the substrate.

5. The surface acoustic wave device as claimed in claim 4, wherein the inner side surface has a height less than that of the SAW device chip.

6. The surface acoustic wave device as claimed in claim 4, wherein the thickness of the ceiling portion of the lid that does not face the SAW device chip increases towards the inner side surface at a constant rate of change.

7. The surface acoustic wave device as claimed in claim 4, wherein the thickness of the ceiling portion of the lid that does not face the SAW device chip increases towards the inner side surface at two constant rates of change or more.

8. The surface acoustic wave device as claimed in claim 4, wherein the thickness of the ceiling portion of the lid that does not face the SAW device chip stepwise increases towards the inner side surface.

9. The surface acoustic wave device as claimed in claim 6, wherein a part of the ceiling portion of the lid that does not face the SAW device chip has a thickness greater than the thickness of the ceiling portion of the lid that increases towards the inner side surface at the constant rate of change.

10. The surface acoustic wave device as claimed in claim 1, wherein the lid is made of epoxy region.
